(19) United States
(12) Patent Application Publication
(10) Pub. No.: US 2026/0097552 A1
(43) Pub. Date: Apr. 9, 2026

(54) IMPRINTING DEVICE, IMPRINTING METHOD, AND METHOD FOR MANUFACTURING ARTICLE

(71) Applicant: CANON KABUSHIKI KAISHA, Tokyo (JP)

(72) Inventor: SATOSHI IINO, Saitama (JP)

(21) Appl. No.: 19/321,925

(22) Filed: Sep. 8, 2025

(30) Foreign Application Priority Data
Oct. 3, 2024 (JP) 2024-174268

(51) Int. Cl. B29C 59/02; B29C 33/30; B29C 37/00

(52) U.S. Cl. CPC B29C 59/022; B29C 33/308; B29C 2037/906

(57) ABSTRACT

An imprinting device includes a measurement unit detecting marks provided on a mold and a substrate, a substrate stage moving in a state of holding the substrate, and a control unit controlling the measurement unit and the substrate stage. The mold has first and second mark groups used for positional alignment with the substrate. The measurement unit acquires information on a relative positional relationship between the first mark group and the second mark group for each individual mold. The control unit controls the substrate stage to positionally align the mold and the substrate on the basis of the information on the relative positional relationship between the first mark group and the second mark group on a first mold and the mold, and information on a superposition error between the first mark group and the second mark group on the first mold and the marks on the substrate.

### BACKGROUND

### Field of the Technology

The present disclosure relates to an imprinting device, an imprinting method, and a method for manufacturing an article.

### Description of the Related Art

There is an imprinting device as one of lithography devices used in manufacturing a semiconductor device and the like. Japanese Patent Laid-Open No. 2015-37122 describes a method for positionally aligning a mold and a substrate in consideration of a positional deviation between alignment marks in alignment processing of the mold and the substrate. However, as described in Japanese Patent Laid-Open No. 2015-37122, adjustment of an alignment offset requires imprinting processing and measurement of a positional deviation between the mold and the substrate, and there is a problem in that it takes time to perform this for each mold.

### SUMMARY

The present disclosure is directed to provide an imprinting device in which a time required to adjust an alignment offset for each individual mold during positional alignment can be shortened.

According to an aspect of the present disclosure, an imprinting device includes a measurement unit configured to detect marks provided on a mold and a substrate, a substrate stage configured to move in a state of holding the substrate, and a control unit configured to control the measurement unit and the substrate stage. The mold has a first mark group and a second mark group used for positional alignment with the substrate. The measurement unit acquires information on a relative positional relationship between the first mark group and the second mark group for each individual mold. The control unit controls the substrate stage to positionally align the mold and the substrate on the basis of the information on the relative positional relationship between the first mark group and the second mark group on a first mold, which is a mold different from the mold, and the mold, and information on a superposition error between the first mark group and the second mark group on the first mold and the marks on the substrate.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing an imprinting device according to a first embodiment.

FIGS. 2A and 2B are views showing a usage example of alignment marks on a mold and a pattern formation region on a substrate.

FIGS. 3A to 3C are views showing a situation in which disposition of the alignment marks within a pattern region differs depending on an individual mold.

FIG. 4 is a flowchart showing processing of the imprinting device according to a first example.

FIGS. 5A to 5G are views showing a situation in which the amount of positional deviation is acquired for each alignment mark by proximity measurement of a mold and a measurement substrate according to the first example.

FIGS. 6A and 6B are views showing pattern positional error information on the mold according to a second example.

FIGS. 7A to 7F are explanatory schematic views of a method for manufacturing an article.

### DESCRIPTION OF THE EMBODIMENTS

Hereinafter, embodiments will be described in detail with reference to the attached drawings. The following embodiments do not limit the disclosure according to the claims. Although the embodiments describe a plurality of features, not all of the plurality of features are essential to the disclosure. In addition, the plurality of features may be combined in any manner. Moreover, in the attached drawings, the same reference numbers are applied to the same or similar constitutions, and duplicate description thereof will be omitted.

### First embodiment

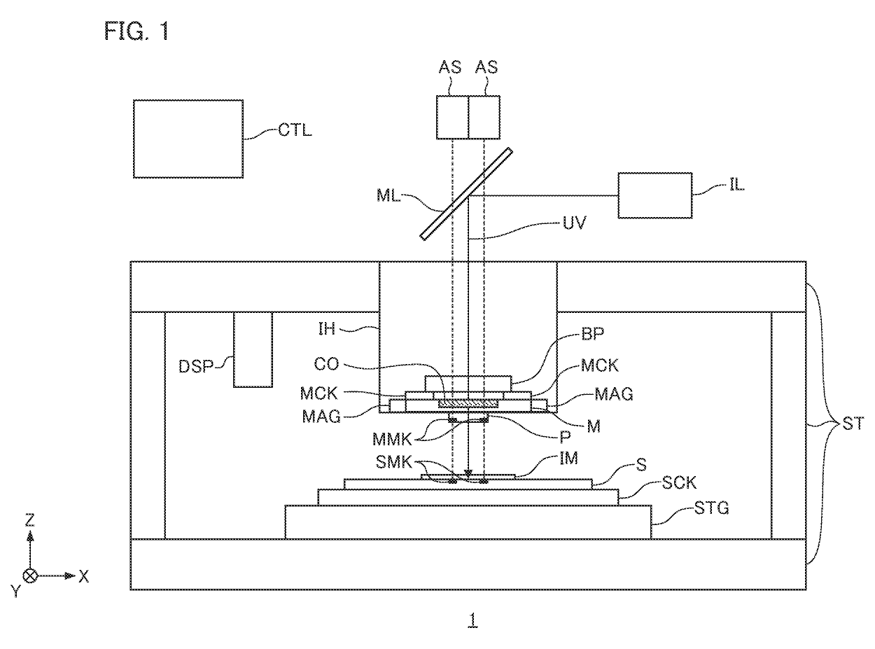

FIG. 1 is a view showing a constitution of an imprinting device 1 according to the present embodiment. The imprinting device 1 is a lithography device transferring the same pattern as that of a mold M to an imprinting material IM disposed on a substrate S by imprinting processing.

The imprinting processing may include contact processing, alignment processing, curing processing, and mold releasing processing. The contact processing (contacting) is processing of bringing a pattern region (pattern portion) P on the mold M into contact with the imprinting material IM disposed in a pattern formation region (shot region, imprinting region) on the substrate S. The alignment processing (positionally aligning) is processing of performing alignment of the pattern formation region on the substrate S and the pattern region P on the mold M in a state in which the mold M is in contact with the substrate S with the imprinting material IM therebetween. The curing processing (curing) is processing of curing the imprinting material IM by irradiation with illumination light UV. The mold releasing processing (mold releasing) is processing of separating the pattern constituted of a cured product of the imprinting material IM from the pattern region P on the mold M. Although it is not shown in the diagrams, the mold M has a mesa portion (projecting pattern formation portion), and the pattern region P having a fine uneven pattern is formed on a lower surface (imprinting surface) of the mesa portion.

A curable composition (which may also be referred to as a resin in an uncured state) which is cured when curing energy is applied thereto is used as an imprinting material. Electromagnetic waves, heat, or the like may be used as the curing energy. For example, electromagnetic waves may be light whose wavelength is selected from a range of 10 nm to 1 mm, for example, infrared rays, visible rays, or ultraviolet rays. The curable composition may be a composition which is cured by irradiation with light, or heating. Among these, a photocurable composition which is cured by irradiation of light may contain at least a polymerizable compound and a photoinitiator and may further contain a non-polymerizable compound or a solvent as necessary. The non-polymerizable compound is at least one kind selected from the group of a sensitizer, a hydrogen donor, an internal mold releasing agent, a surfactant, an antioxidant, a polymer component, and the like. The imprinting material may be disposed on the substrate in a droplet shape, or an island shape or a film shape formed by a plurality of connected droplets. The viscosity of the imprinting material (viscosity at 25°C) may be 1 mPa·s to 100 mPa·s, for example.

In the present embodiment, directions will be indicated in an XYZ coordinate system having a direction parallel to a surface of the substrate S as an XY plane. In the XYZ coordinate system, directions parallel to an X axis, a Y axis, and a Z axis are regarded as an X direction, a Y direction, and a Z direction, respectively, and rotation around the X axis, rotation around the Y axis, and rotation around the Z axis are regarded as θX, θY, and θZ, respectively.

The imprinting device 1 includes an imprinting head IH inside a structure ST. The imprinting head IH includes a drive unit (not shown) for moving the mold M in the Z direction during the contact processing of bringing the imprinting material IM on the substrate S into contact with the mold M, and the mold releasing processing of separating the mold M from the imprinting material IM on the substrate S. The drive unit is not limited to the Z direction and may also be constituted to be able to be driven in the X direction and the Y direction. The drive unit of the imprinting head IH may be constituted to be able to move the mold M not only in the Z direction but also in the X direction and the Y direction. Moreover, it may be constituted to have a tilting function of driving the mold M in the θX and θY directions. The imprinting head IH includes a mold holding unit MCK for holding the mold M. The mold holding unit MCK holds the mold M by attracting an outer circumferential region of a contact surface with respect to the mold M using a vacuum suction force or an electrostatic force.

In addition, the imprinting head IH includes a shape correction unit MF. The shape correction unit MF may deform the shape of the pattern region P on the mold M in the XY directions. For example, the shape correction unit MF may deform the pattern region P by applying a force to four side surfaces of the mold M. The imprinting head IH includes a pressure mechanism BP for applying a pressure to the surface on a side opposite to the pattern region P on the mold M. A core-out CO may be formed in the mold M. The core-out CO may have a shape formed by hollowing out the side opposite to the pattern region P in a cylindrical recessed shape. When a pressure is applied to the core-out CO by the pressure mechanism BP, the pattern region P is deformed into a shape projecting toward the substrate S. Accordingly, in the contact processing of the mold M and the substrate S during imprinting, the pattern region P on the mold M can be brought into contact with the substrate S from its center portion. For this reason, the inside of the pattern region P on the mold M can be efficiently filled with the imprinting material IM.

The imprinting device 1 includes a substrate stage STG inside the structure ST. The substrate stage STG includes a drive unit (not shown) for performing positional alignment of the mold M and the substrate S in the alignment processing. The drive unit of the substrate stage STG is driven in the X direction, the Y direction, and the θZ direction to positionally set the substrate S with high accuracy. In addition, the drive unit of the substrate stage STG may be constituted to have a tilting function of driving it in the θX and θY directions. The substrate stage STG includes a substrate holding unit SCK for adsorbing and holding the substrate S. That is, the substrate stage STG can move the substrate S in at least the X direction, the Y direction, and the θZ direction in a state of holding it.

The imprinting device 1 includes a measurement unit AS. In the alignment processing, the measurement unit AS observes alignment marks MMK on the mold M and alignment marks SMK on the substrate S and measures a superposition error between both the marks in the XY directions. A plurality of (for example, four or more) measurement units AS may be mounted to accurately measure the superposition error between the mold M and the substrate S. In addition, the measurement unit AS may be driven in the XY directions to be able to measure a plurality of alignment marks at different positions on the mold M and the substrate S.

The imprinting device 1 includes an illumination unit (illumination system) IL. In the curing processing, in a state in which the pattern region P on the mold M is in contact with the imprinting material IM disposed on the substrate S, the illumination unit IL cures the imprinting material IM by irradiating the imprinting material IM with the illumination light UV for curing. The illumination light UV may irradiate the imprinting material IM via a mirror ML.

The imprinting device 1 includes a dispenser (coating unit) DSP. The dispenser DSP disposes the imprinting material IM in the pattern formation region (shot region, imprinting region) on the substrate S. The imprinting material IM may be disposed in the pattern formation region on the substrate S in a state in which the substrate S is driven by the substrate stage STG and when the dispenser DSP discharges the imprinting material IM in synchronization with the driving.

The imprinting device 1 includes a control unit CTL. The control unit CTL includes a CPU or a memory, is constituted of at least one general-purpose or dedicated computer, and is connected to each constituent element of the imprinting device 1 through a line. In addition, the control unit CTL also functions as a control unit configured to comprehensively control operation, adjustment, and the like of each constituent element of the entire imprinting device 1 in accordance with a program stored in the memory. For example, the control unit CTL may control the imprinting head IH, the substrate stage STG, the measurement unit AS, the illumination unit IL, and the dispenser DSP. In addition, the control unit CTL may be constituted integrally with other parts of the imprinting device 1 (inside a common casing) or may be constituted separately from other parts of the imprinting device 1 (inside a different casing). Alternatively, the control unit CTL may be installed in a location separate from the imprinting device 1 and control it remotely.

In addition, the control unit CTL may be constituted of a programmable logic device (PLD) such as a field programmable gate array (FPGA), or an application specific integrated circuit (ASIC).

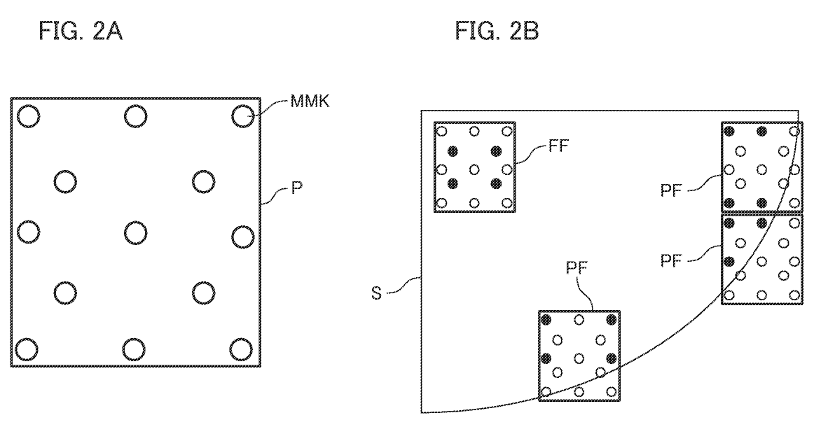

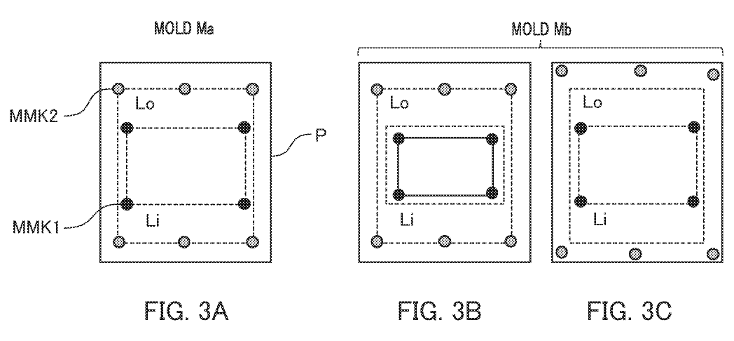

Next, a phenomenon in which alignment of the entire pattern region P deviates depending on an individual mold will be described using a full shot FF (which will be described below) as an example. FIGS. 2A and 2B are views showing a usage example of the alignment marks MMK on the mold M and the pattern formation region on the substrate S. FIGS. 3A to 3C are views showing a situation in which disposition of the alignment marks MMK within the pattern region P differs depending on the individual mold M.

Hereinafter, a full field (FF) region, which is a shot in which the pattern region P on the mold M and the pattern formation region on the substrate S overlap 100%, will be referred to as the full shot FF. Moreover, a partial field (PF) region, which is a shot in which only a part of the pattern formation region on the substrate S overlaps the pattern region P on the mold M in an outer circumferential portion of the substrate S, will be referred to as a missing shot PF.

FIG. 2A is a view showing a disposition state of the alignment marks MMK disposed over the entire pattern region P on the mold M. The reason why a plurality of alignment marks MMK are disposed over the entire pattern region P is to cope with alignment of the missing shot PF shown in FIG. 2B. As shown in FIG. 2B, black circle marks of the plurality of alignment marks MMK indicate marks used for alignment. Further, white marks indicate marks not used for alignment. Since a plurality of patterns of a region in which the mold M and the substrate S overlap are present in the missing shot PF, there is a need for the alignment marks MMK to be disposed over the entire pattern region P.

FIG. 3A is a view showing a mold Ma as a certain individual mold (one mold of a plurality of molds). In addition, FIGS. 3B and 3C are views showing a mold Mb as an individual different from the mold Ma. In each of the alignment marks MMK, at the time of alignment of the mold M and the substrate S in the full shot FF, marks observed by the measurement unit AS will be regarded as a first alignment mark group MMK1, and the remaining marks will be regarded as a second alignment mark group MMK2. The first alignment mark group MMK1 and the second alignment mark group MMK2 are provided within the pattern region P on the mold M. As shown in FIGS. 3A to 3C, the second alignment mark group MMK2 is provided at various positions including an end portion of the pattern region P (provided over the entire pattern region). However, here, in order to simplify the description, an example in which it is disposed only in the outer circumferential portion of the pattern region P is shown.

For the first alignment mark group MMK1, marks disposed in a part closer to the center of the pattern region P may be selected. In the imprinting processing and alignment of the full shot FF, in a state in which the imprinting material IM does not completely fill the insides of the alignment marks MMK and there are gaps, a measurement signal of the measurement unit AS involves noise so that correct measurement will not be possible. Here, since the imprinting material IM fills the alignment marks MMK more quickly in a part closer to the center of the pattern region P, measurement and alignment of the marks can be performed more quickly. From the viewpoint of throughput, if more time can be spent on alignment within a limited imprinting time, higher alignment accuracy is achieved. This is the reason why the marks disposed in a part closer to the center of the pattern region P are selected as the first alignment mark group MMK1.

In the mold Ma shown in FIG. 3A as an example, in the alignment processing, it is assumed that the first alignment mark group MMK1 is in a state of being positionally aligned with the alignment marks SMK (not shown) on the substrate S along a dotted line Li on the inward side. At this time, the position of the second alignment mark group MMK2 is a position along a dotted line Lo on the outward side.

Meanwhile, in the mold Mb shown in FIG. 3B as an example, the position of the first alignment mark group MMK1 deviates to the inward side with respect to the dotted line Li on the inward side that is the position of the first alignment mark group MMK1 on the mold Ma. This is because there is a difference between individuals in the positional relationship between the inward side and the outward side of the pattern region P due to a manufacturing error in the mold. In the alignment processing, there is no change in the alignment marks SMK on the substrate S at the position of the dotted line Li. Thus, in the alignment processing, the imprinting device 1 deforms the pattern region P on the mold Mb by the shape correction unit MF or the like such that the first alignment mark group MMK1 on the mold Mb aligns with the position of the alignment marks SMK on the substrate S.

After the alignment processing in which shape correction of the mold Mb has been performed, the first alignment mark group MMK1 is at the position of the dotted line Li as in FIG. 3C from the original position. At this time, the second alignment mark group MMK2 on the mold Mb also moves in a similar manner. In the mold Mb, the second alignment mark group MMK2 was originally located on the same dotted line Lo as the mold Ma, but it has moved, due to the alignment processing, in the outward direction of the dotted line Lo as in FIG. 3C.

Both FIGS. 3A and 3C show a state in which the first alignment mark group MMK1 is aligned with the position of the alignment marks SMK on the substrate S by alignment. However, the position of the second alignment mark group MMK2 on the mold Mb is a position on the outward side compared to the case of the mold Ma, and the position of the second alignment mark group MMK2 differs between the two different molds. This means that the degree of deviation of the entire pattern region P after alignment differs depending on the mold.

From above, even if the superposition error between the entire pattern region P and the substrate S is small in a certain individual mold, when imprinting is performed with a different individual mold in a similar manner, the superposition error may become significant. In the related art, there was a need to adjust an alignment offset for each individual mold to cope with this inter-individual difference between the molds M. Adjustment of an alignment offset denotes that the amount of positional deviation between a transfer pattern on the mold M and the substrate S is measured using an external superposition measurement instrument and the measurement unit AS is adjusted such that its measurement values fall within an allowable range. At semiconductor device manufacturing sites, imprinting devices (lithography devices) are often adjusted with reference to measurement values of an external superposition measurement instrument specialized in superposition measurement. For this reason, in the related art, in order to adjust an alignment offset, there was a need to perform imprinting and measurement using an external superposition measurement instrument for each individual mold, which took time. The present embodiment provides a method for correcting such an inter-individual difference between a plurality of molds requiring no imprinting processing.

### First example

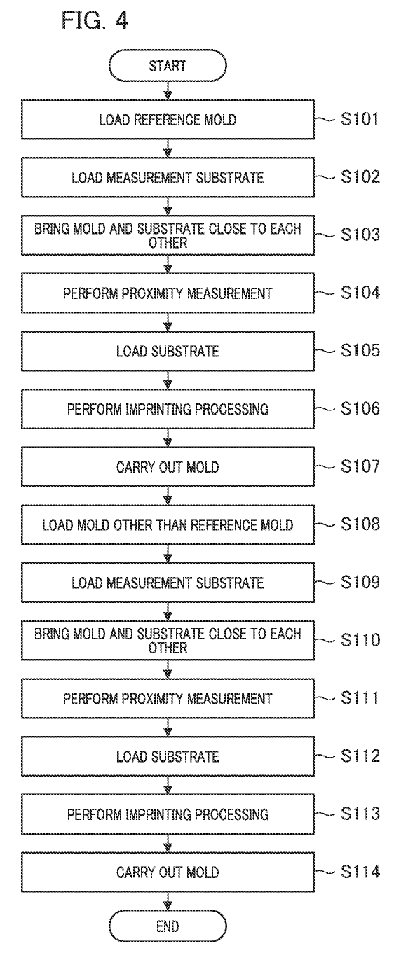

Hereinafter, processing performed by the imprinting device 1 according to a first example will be described using the flowchart in FIG. 4. FIG. 4 is a flowchart showing processing of the imprinting device 1 according to the first example. FIG. 4 shows a flow in which S101 to S107 are performed only with a reference mold (first mold) and the processing of S108 to S114 is performed with a different mold (second mold) other than the reference mold. Here, the reference mold is a mold used for calculating a difference for each individual mold (a mold used as a reference in calculation of a difference). In addition, each process of the following processing is realized by the control unit CTL of the imprinting device 1 executing a program stored in the memory. In addition, each process (step) will be notated by adding S to the beginning of it and notation of the process (step) will be omitted.

In addition, as a premise for the processing described below, an alignment offset has already been adjusted for the reference mold Ma with reference to the measurement values of the external superposition measurement instrument from imprinting results in the past. That is, before the processing shown in FIG. 4 starts, a target position of the measurement unit AS has already been adjusted such that the measurement values of the external superposition measurement instrument become small.

In S101, the control unit CTL causes the reference mold Ma to be loaded onto the mold holding unit MCK of the imprinting head IH. In S102, the control unit CTL causes a measurement substrate Sm to be loaded onto the substrate holding unit SCK of the substrate stage STG. Here, the reason for using the measurement substrate Sm is to measure the shape of the mold Ma as the amount of relative positional deviation with respect to the measurement substrate Sm in S104, which will be described below. The measurement substrate Sm has the same design as the substrate S to be loaded onto the substrate stage STG in S105, which will be described below. In other words, the measurement substrate Sm has a constitution similar to that of the substrate S according to the present embodiment. In addition, the measurement substrate Sm is a substrate which is used only for measurement and is a substrate which is not actually subjected to the imprinting processing.

In S103, the control unit CTL causes the drive unit of the imprinting head IH to be driven in a direction in which a gap between the mold Ma and the measurement substrate Sm is reduced. Since the processing of S104 to be performed next requires the measurement unit AS to measure a relative shape deviation between the mold Ma and the measurement substrate Sm in a proximity state, the control unit CTL causes the drive unit of the imprinting head IH to be driven in the Z direction to bring the mold Ma closer to the measurement substrate Sm. The control unit CTL controls the drive unit of the imprinting head IH such that the mold Ma does not come into contact with the measurement substrate Sm. Since the intensity of signals detected by the measurement unit AS from the alignment marks MMK and SMK increases as the gap between the mold Ma and the measurement substrate Sm becomes smaller, the measurement accuracy of the relative shape deviation between the mold Ma and the measurement substrate Sm is improved. For this reason, it may have a smaller gap between the mold Ma and the measurement substrate Sm. Here, in S103, even if the mold Ma and the measurement substrate Sm are in a non-contact state, it is desirable that the gap between the mold Ma and the measurement substrate Sm be 10 μm or smaller in order for the measurement unit AS to be able to measure the relative shape deviation between the mold Ma and the measurement substrate Sm with sufficient accurately.

In S104, the control unit CTL measures the relative shape deviation of the alignment marks MMK on the mold Ma with respect to the alignment marks SMK on the measurement substrate Sm in a state in which the mold Ma and the measurement substrate Sm are not in contact with each other. During the processing of S104, the control unit CTL controls the measurement unit AS to measure the amount of positional deviation between the first alignment mark group MMK1 and the second alignment mark group MMK2. Here, when the amount of positional deviation is measured, it is performed in a state in which the mold Ma is brought closer to the measurement substrate Sm (non-contact state). The amount of positional deviation between the first alignment mark group MMK1 and the second alignment mark group MMK2 measured in S104 is used for positional alignment of the mold Ma and the substrate S in S106, which will be described below. The measurement unit AS measures the amount of positional deviation of the alignment marks MMK on the mold Ma with respect to the alignment marks SMK on the measurement substrate Sm in a state in which the mold Ma and the measurement substrate Sm are not in contact with each other (non-contact state), and acquires the measured amount of positional deviation as an amount of relative positional deviation.

Here, in FIG. 3A, a magnification measurement value obtained from the first alignment mark group MMK1 on the mold Ma will be regarded as MAGa1, and a magnification measurement value obtained from the second alignment mark group MMK2 will be regarded as MAGa2. In this case, the difference between the two is obtained by MAGa=MAGa2–MAGa1. This means the difference within the pattern region between the alignment position in the mold Ma and the entire pattern region. In other words, the measurement unit AS acquires the difference within the pattern region between the alignment position and the entire pattern region as information on the relative positional relationship between the first alignment mark group and the second alignment mark group MMK2 on the mold Ma. The difference within the pattern region between the alignment position and the entire pattern region is also acquired in a state in which the mold Ma and the measurement substrate Sm are not in contact with each other.

Similarly, SHIFTa, ROTa, and SKEWa are obtained respectively for translation, rotation, and orthogonal errors as the difference within the pattern region between the first alignment mark group MMK1 and the second alignment mark group MMK2. That is, in S104, the difference MAGa which is a magnification difference within the pattern region, the difference SHIFTa which is a translation difference within the pattern region, the difference ROTa which is a rotation difference within the pattern region, and the difference SKEWa which is an orthogonal error difference within the pattern region are acquired respectively. The control unit CTL stores the information on these acquired differences within the pattern region as the measurement results in S104 in a storage medium such as a memory.

In FIGS. 3A to 3C, an example in which the position of the first alignment mark group MMK1 differs between individual molds has been described. However, a case in which the second alignment mark group MMK2 or both differ between individual molds is also considered. Thus, it can be said that there is a need to acquire both MAGa and MAGb and obtain the difference within the pattern region. The difference within the pattern region on the mold Ma acquired in the processing of S104 is not used in the imprinting processing using the mold Ma but is used in the processing with respect to the mold Mb, which will be described below. The processing of S104 may be performed in one pattern formation region on the measurement substrate Sm or may be performed in a plurality of pattern formation regions. If it is performed in a plurality of pattern formation regions, for example, acquired results may be averaged to obtain the difference within the pattern region.

In measurement of the amount of relative positional deviation between the mold Ma and the measurement substrate Sm performed in S104, the imprinting head IH and the substrate stage STG are not in a strictly stationary state and are vibrating in at least any of the X direction, the Y direction, and the θZ direction, for example. For this reason, the relative positions of the mold Ma and the measurement substrate Sm are not constant. Therefore, processing of eliminating the influence of vibration from the measurement values of the measurement unit AS is required.

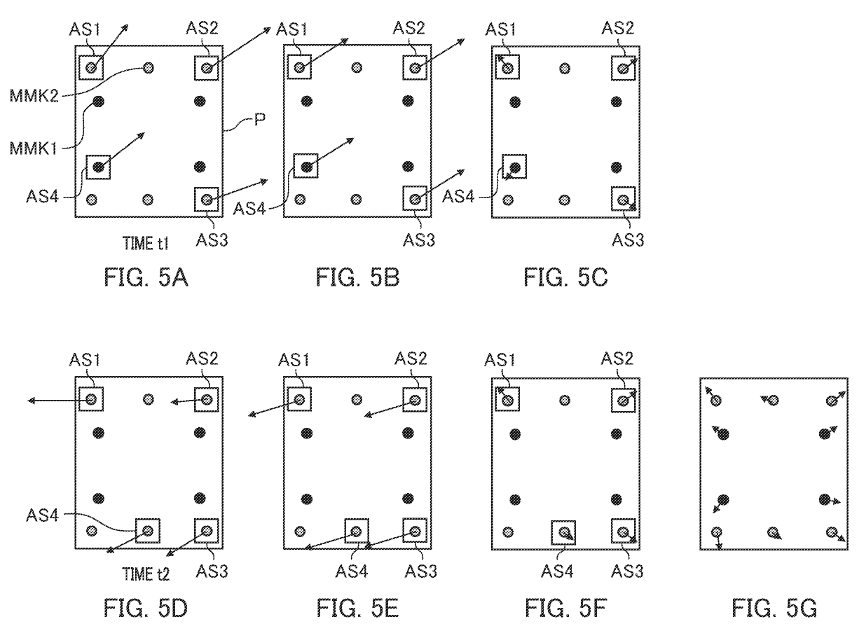

Hereinafter, with reference to FIGS. 5A to 5G, a method for eliminating an influence of vibration in a state in which four measurement units AS1, AS2, AS3, and AS4, as examples of the measurement unit AS, capable of simultaneous measurement are mounted in the imprinting device 1 will be described. AS1, AS2, and AS3 of the four measurement unit AS each measure the same measurement point (alignment mark) at all times, and the remaining measurement unit AS4 moves and measures different measurement points (alignment marks) in sequence. That is, some measurement units AS of the plurality of measurement units AS each detect an alignment mark at the same position in all measurement, and the remaining measurement unit AS other than the measurement units detects the alignment marks at different positions every time measurement is performed.

FIGS. 5A to 5G are views showing a situation in which the amount of positional deviation for each alignment mark is acquired by proximity measurement (non-contact measurement) of the mold M and the measurement substrate Sm. For example, FIGS. 5A and 5D show a situation in which the measurement unit AS measures the superposition error between the alignment marks MMK on the plurality of molds Ma and the alignment marks SMK on the measurement substrate Sm at each different time, such as a time t1 and a time t2. In FIG. 5D, the three measurement units AS1, AS2, and AS3 of the measurement unit AS each measure the same alignment mark as that in FIG. 5A, but only the measurement unit AS4 measures another alignment mark different from that in FIG. 5A. Here, the arrows indicated in FIGS. 5A to 5G represent the amount of relative positional deviation between the alignment marks on the mold Ma and the measurement substrate Sm at the corresponding position.

The arrows indicated in FIG. 5A include components of the arrows indicated in FIG. 5B as the influence of vibration (amount of shift) at the time of measurement of the imprinting head IH and the substrate stage STG in the X direction and the Y direction. The control unit CTL obtains the components in FIG. 5B as the amount of shift, which is the influence of vibration at the time t1, from the measurement data in FIG. 5A, and FIG. 5C shows a result obtained by subtracting the obtained amount of shift from the measurement data in FIG. 5A. Further, the arrows indicated in FIG. 5C become the amount of positional deviation between the mold Ma and the measurement substrate Sm at the time t1. FIG. 5B, in which the amount of shift as the influence of vibration at the time t1 is indicated by the arrows, can be obtained as the amount of relative movement between the mold M and the substrate S, for example, by averaging displacement of each measurement point (measurement value) in FIG. 5A during measurement of the superposition error.

Similarly, the arrows indicated in FIG. 5D include components of the arrows indicated in FIG. 5E as the influence of vibration (amount of shift) at the time of measurement of the imprinting head IH and the substrate stage STG in the X direction and the Y direction. The control unit CTL obtains the components in FIG. 5E as the amount of shift, which is the influence of vibration at the time t2, from the measurement data in FIG. 5D, and FIG. 5F shows a result obtained by subtracting the obtained amount of shift from the measurement data in FIG. 5D. In other words, the control unit CTL acquires the amount of shift which is the influence of vibration on the basis of the detection results (measurement data) with respect to a plurality of alignment marks acquired at the same timing (same time) and subtracts the acquired amount of shift from the detection results. Further, the arrows indicated in FIG. 5F become the amount of positional deviation between the mold Ma and the measurement substrate Sm at the time t2.

In FIGS. 5C and 5F, the amount of positional deviation between the mold Ma and the measurement substrate Sm in the measurement units AS1, AS2, and AS3 becomes the same. In this manner, the control unit CTL sequentially changes a measurement target of the measurement unit AS4 and integrates data after vibration components are subtracted. Further, the results shown in FIG. 5G (amount of positional deviation between the mold and the substrate) are finally obtained. That is, the control unit CTL acquires the amount of positional deviation between the mold and the substrate for all the alignment mark in the pattern formation region by integrating all the detection results from which the amount of shift has been subtracted. If the measurement accuracy is insufficient and the amounts of positional deviation of AS1, AS2, and AS3 in FIGS. 5B and 5E do not coincide with each other, this is dealt with by increasing the number of times of measurement of the measurement unit AS to increase the averaging effect.

In S105, the control unit CTL unloads the measurement substrate Sm from the substrate holding unit SCK. Thereafter, the substrate S used for imprinting is loaded onto the substrate holding unit SCK of the substrate stage STG.

In S106, the control unit CTL performs the imprinting processing. Regarding the imprinting processing, first, the control unit CTL controls the dispenser DSP to supply the imprinting material IM to the pattern formation region on the substrate S from above (supplying). In the supplying, the dispenser DSP discharges the imprinting material IM onto the pattern formation region on the substrate S in accordance with the timing of the substrate stage STG scanning below the dispenser DSP. A material enhancing adhesion to the imprinting material IM is applied to the surface of the substrate S and plays a role of keeping the imprinting material IM on the substrate S side in the subsequent mold releasing.

Next, the control unit CTL controls the imprinting head IH to bring the mold Ma into contact with the substrate S with the imprinting material IM therebetween (contacting). At this time, the pattern region P may be caused to protrude in a shape projecting toward the substrate S by applying a pressure to a surface on a side opposite to the pattern region P such that the pattern region P on the mold M is brought into contact with the substrate S and the imprinting material IM from its center portion. They are brought into contact with each other until the imprinting material IM sufficiently spreads between the pattern region P on the mold Ma and the substrate S.

Next, during the alignment processing (positional alignment processing), the control unit CTL controls the measurement unit AS to measure the superposition error between the alignment marks SMK on the substrate S and the first alignment mark group MMK1 on the mold Ma detected by the measurement unit AS. Further, the control unit CTL controls the substrate stage STG on the basis of the measured superposition error to perform positional alignment of the substrate S and the mold Ma (positional alignment of the pattern formation region on the substrate S and the pattern region P on the mold Ma). The superposition error corrected in the processing of the positional alignment may be a translation component, a rotation component, a magnification component, or a distortion component (for example, a component of a rhombic shape, a trapezoidal shape, or the like), for example. The control unit CTL controls the substrate stage STG on the basis of the computed superposition error so as to reduce the superposition error in the translation and rotation components. In addition, the control unit CTL controls driving of the shape correction unit MF so as to reduce the superposition error in the magnification component and the distortion component on the basis of the superposition error in the magnification component and the distortion component. When the distortion component is corrected, the substrate S may be locally subjected to thermal expansion to change the shape of the pattern formation region on the substrate S by irradiating a predetermined position on the substrate S with light having a certain intensity in accordance with driving of the shape correction unit MF.

Next, the control unit CTL controls the illumination unit IL to irradiate the imprinting material IM on the substrate S with the illumination light (imprinting light) UV (curing). The imprinting material IM is cured by irradiation with the illumination light UV. Next, the control unit CTL controls the imprinting head IH to separate the cured imprinting material IM disposed on the substrate S and the pattern region P on the mold Ma (mold releasing). Accordingly, the uneven pattern of the pattern region P on the mold M is transferred to the imprinting material IM, and a curable composition pattern is formed.

In S107, the control unit CTL controls a carry-out mechanism (not shown) to carry out the mold Ma from the imprinting device 1. The amount of positional deviation between the transfer pattern on the mold Ma and the substrate S may be measured using an external superposition measurement instrument after the processing of S107 (after the mold Ma has been carried out). Here, in the mold Ma, as described above, since an alignment offset has already been adjusted, the measurement values of the external superposition measurement instrument which fall within the allowable range are obtained. Therefore, if an alignment offset has been adjusted in advance, measurement by an external superposition measurement instrument may be omitted.

In S108, the control unit CTL loads the mold Mb, which is a mold different from the mold Ma (reference mold), onto the mold holding unit MCK of the imprinting head IH. Next, in S109, the control unit CTL loads the measurement substrate Sm onto the substrate holding unit SCK of the substrate stage STG. Next, in S110, the control unit CTL causes the drive unit of the imprinting head IH to be driven in a direction in which a gap between the mold Mb and the measurement substrate Sm is reduced. Since the details of the processing of S109 and S110 are similar to those of S102 and S103, respectively, detailed description will be omitted. In S109, the same measurement substrate Sm as that used for the mold Ma is used (loaded) in order to eliminate the influence on the substrate due to a difference between the individuals.

In S111, similarly to S104, the control unit CTL measures the relative shape deviation of the alignment marks MMK on the mold Mb with respect to the alignment marks SMK on the measurement substrate Sm in a state in which the mold Mb and the measurement substrate Sm are not in contact with each other. Here, in FIG. 3A, a magnification measurement value obtained from the first alignment mark group MMK1 on the mold Mb will be regarded as MAGb1, and a magnification measurement value obtained from the second alignment mark group MMK2 will be regarded as MAGb2. In this case, the difference between the two is obtained by Difference MAGb=MAGb2–MAGb1. This means the difference within the pattern region between the alignment position in the mold Mb and the entire pattern formation region. In other words, the measurement unit AS acquires the difference within the pattern region between the alignment position and the entire pattern region as information on the relative positional relationship between the first alignment mark group MMK1 on the mold Mb and the second alignment mark group MMK2. The difference within the pattern region between the alignment position and the entire pattern region is acquired, similarly to S104, in a state in which the mold Mb and the measurement substrate Sm are not in contact with each other.

Further, similarly to S104, SHIFTb, ROTb, and SKEWb are obtained respectively for the translation, the rotation, and the orthogonal errors (orthogonal components) as the difference within the pattern region between the first alignment mark group MMK1 and the second alignment mark group MMK2. The control unit CTL stores the information on these acquired differences within the pattern region as the measurement results in S111 in a storage medium such as a memory.

In S112, the control unit CTL unloads the measurement substrate Sm from the substrate holding unit SCK. Thereafter, the substrate S used for the imprinting processing (for performing the imprinting processing) is loaded onto the substrate holding unit SCK of the substrate stage STG.

In S113, similarly to S106, the control unit CTL performs the imprinting processing. Here, S113 partially differs from S106 in details of the processing. Hereinafter, description of the processing similar to that of S106 will be omitted, and processing unique to S113 will be described.

In S106, the pattern formation region on the substrate S and the pattern region P on the mold Ma are positionally aligned on the basis of the superposition error between the first alignment mark group MMK1 and the second alignment mark group MMK2 on the mold Ma. Meanwhile, in S113, the mold Mb and the substrate S are positionally aligned on the basis of the information on the relative positional relationship between the first alignment mark group MMK1 and the second alignment mark group MMK2 on the mold Ma and the mold Mb, and the information on the superposition error between the mold Ma and the substrate S measured in S106. Similarly to S106, the control unit CTL controls the substrate stage STG to positionally align the pattern formation region on the substrate S and the pattern region P on the mold Mb.

Specifically, regarding the difference within the pattern region which is information on the relative positional relationship between the first alignment mark group MMK1 and the second alignment mark group MMK2 on the mold, the inter-individual mold difference between the mold Ma and the mold Mb is calculated. Further, the inter-individual difference is applied as an additional alignment offset at the time of alignment with the substrate S by the mold Mb (positional alignment). The inter-individual mold difference between the mold Ma and the mold Mb is calculated by the control unit CTL.

Here, taking the magnification as an example, an inter-individual mold difference MAGba is obtained as the amount of change in the difference MAGb which is the difference within the pattern region on the mold Mb with respect to the difference MAGa which is the difference within the pattern region on the mold Ma (MAGba=MAGb–MAGa). Further, the alignment target position of the measurement unit AS is shifted by the amount of this inter-individual mold difference MAGba. That is, the control unit CTL uses the amount of change from the mold Ma as a correction value in positional alignment for each mold on the basis of the information on the relative positional relationship between the first alignment mark group MMK1 and the second alignment mark group MMK2 on the mold Ma and the mold Mb.

In this manner, the control unit CTL acquires the inter-individual difference between the mold Ma (first mold) and at least one second mold (mold Mb) different from the mold Ma as the correction value at the time of positional alignment of the mold and the substrate. In the foregoing description, the magnification has been taken as an example. However, similarly for the translation, the rotation, and the orthogonal errors (orthogonal components) as well, the amount of change is used as the correction value in positional alignment for each mold. That is, the control unit CTL uses the amount of change in each of the magnification, the translation, the rotation, and the orthogonal errors (orthogonal components) as the correction value in positional alignment of the mold Mb and the substrate S.

Since the difference within the pattern region of each of the mold Ma and the mold Mb is obtained from the relative shape deviation based on the same measurement substrate Sm, the inter-individual mold difference, which is the difference therebetween, represents only the difference between the individual molds. Here, since the position of the first alignment mark group MMK1 on the mold Mb deviates with respect to the reference mold Ma, if alignment is performed as it stands, the position of the entire pattern region will deviate to the outward side from the mold Ma, similarly to the example shown in FIG. 3B. However, this problem can be resolved by applying the inter-individual mold difference MAGba as an additional alignment offset.

For example, if the difference MAGa which is the difference within the pattern region on the mold Ma for the magnification is 1 ppm and the difference MAGb which is the difference within the pattern region on the mold Mb is 2 ppm, the inter-individual mold difference MAGba becomes –1 ppm. This offset acts to cause the target position in the alignment processing of the mold Mb to deviate by –1 ppm. As a result, the position of the second alignment mark group MMK2 representing the position of the entire pattern region after alignment becomes the same for the mold Ma and the mold Mb. Further, similarly to the foregoing description, for the translation, the rotation, the orthogonal errors as well, the inter-individual mold difference is applied as an additional alignment offset.

In S114, the control unit CTL controls a carry-out mechanism (not shown) to carry out the mold Ma from the imprinting device 1. After the processing of S114 (after the mold Ma is carried out), similarly to S107, the amount of positional deviation between the transfer pattern on the mold Mb and the substrate S may be measured using an external superposition measurement instrument. In the mold Mb, the amount of positional deviation from the mold Ma, in which the alignment offset has already been adjusted as described above, is corrected at the time of alignment as the inter-individual mold difference. Thus, a value which falls within the allowable range can be obtained for the superposition error measured for the transfer pattern on the mold Mb using an external superposition measurement instrument. Therefore, if an alignment offset has been adjusted in advance, measurement by an external superposition measurement instrument may be omitted. The time required to adjust an alignment offset for each individual mold during positional alignment can be shortened by omitting measurement using an external superposition measurement instrument.

For the missing shot PF as well, the inter-individual mold difference is corrected by a method similar to that for the full shot FF. However, in the missing shot PF, disposition of the alignment marks MMK differs for each pattern formation region. For this reason, the difference within the pattern region between the first alignment mark group MMK1 and the second alignment mark group MMK2 is obtained for each pattern formation region, and the difference with respect to the mold Ma (reference mold) is corrected.

When the pattern formation region on the substrate S and the pattern region P on the mold Ma are positionally aligned, it has been performed by the control unit CTL controlling the drive unit of the substrate stage STG. However, for example, it may be performed by controlling the drive unit of the imprinting head IH. In addition, for example, for the positional alignment, it may be performed by controlling each of the drive unit of the substrate stage STG and the drive unit of the imprinting head IH. That is, the control unit CTL can perform the alignment by controlling at least one of the drive units of the substrate stage STG and the imprinting head IH.

As above, in the related art, in addition to the imprinting processing, there was a need to perform measurement for each individual mold using an external superposition measurement instrument, for calculation of an alignment offset. However, according to the imprinting device 1 of the present example, the inter-individual mold difference in the superposition error can be corrected by only the imprinting device 1. Similarly to the mold Mb, the inter-individual mold difference can be eliminated by correcting the difference with respect to the reference mold Ma.

Hereinabove, according to the imprinting device 1 of the present example, since the inter-individual mold difference in the superposition error can be corrected without using an external superposition measurement instrument, the time required to adjust an alignment offset for each individual mold during positional alignment can be shortened. Accordingly, throughput is also improved.

### Second example

In the first example, a method, in which the mold Ma or the mold Mb is brought close to the measurement substrate Sm and measured by the measurement unit AS, has been described as a way of acquiring an inter-individual mold difference in positional alignment. In a second example, a method for obtaining an inter-individual mold difference using pattern positional error information (pattern manufacturing error information) which is manufacturing data for each individual mold M will be described.

Due to manufacturing errors in the mold M, distortion in the horizontal direction within the pattern region P differs for each individual mold M. Regarding a way of ascertaining this distortion, the amount of positional deviation of distortion measurement marks DMK from design coordinates is acquired by measuring the distortion measurement marks DMK disposed within the pattern region P for each mold using an absolute length measurement instrument (not shown). In the second example, the amount of positional deviation of the distortion measurement marks DMK from the design coordinates, which has been acquired using an absolute length measurement instrument, is adopted as the pattern positional error information. The absolute length measurement instrument is disposed outside the imprinting device 1.

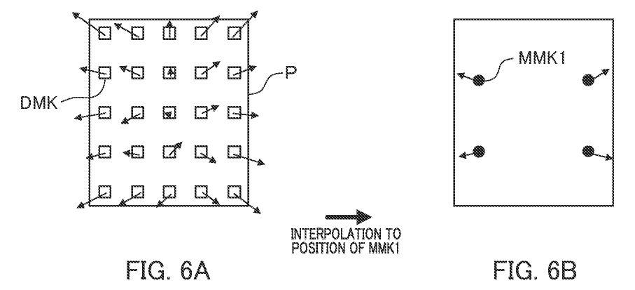

In the second example, similarly to the first example, the amount of positional deviation in the coordinates (position) of the first alignment mark group MMK1 used for positional alignment is obtained. Hereinafter, description will be given with reference to FIGS. 6A and 6B. FIGS. 6A and 6B are views showing the pattern positional error information on the mold M according to the second example.

Here, in FIG. 6A, regarding the pattern positional error information on the mold M, the amounts of positional deviation of the distortion measurement marks DMK from the design coordinates at each point are indicated by arrows. In the pattern region P, since plurality of different marks cannot be disposed in the same coordinates, the coordinates of the distortion measurement marks DMK differ from the coordinates of the first alignment mark group MMK1 on the mold M. Thus, as shown in FIG. 6B as an example, in the second example, the control unit CTL acquires the amount of positional deviation in the coordinates (position) of the first alignment mark group MMK1 by interpolation and extrapolation from the pattern positional error information. Specifically, the amount of positional deviation in the coordinates of the first alignment mark group MMK1 is obtained from the coordinates of the distortion measurement marks DMK and the amount of positional deviation from the coordinates by interpolation and extrapolation, and this is acquired. Meanwhile, similarly to the first example, the position of the second alignment mark group MMK2 may be used as the amount of positional deviation of the entire pattern region P, but the second example is not limited to this. For example, the amount of positional deviation at the position of the mark, which is a measurement target of an external superposition measurement instrument, may be obtained by interpolation and extrapolation from the coordinates of the distortion measurement marks DMK and the amount of positional deviation from the coordinates.

Hereinafter, acquisition of an alignment offset according to the second example performed by the control unit CTL will be described using the magnification as an example. The magnification calculated from the amount of positional deviation in the coordinates of the first alignment mark group MMK1, which is obtained by interpolation and extrapolation from the pattern positional error information, will be regarded as MAGa1. Similarly, the magnification calculated from a positional deviation in any coordinates of the entire pattern region P, which is obtained by interpolation and extrapolation, will be regarded as MAGa2. Then, the difference between the two, that is, the difference MAGa which is the difference within the pattern region is obtained by MAGa=MAGa2–MAGa1. Similarly for the mold Mb as well, the difference MAGb which is the difference within the pattern region is obtained, and the inter-individual mold difference MAGba=MAGb–MAGa is applied as the additional alignment offset for the mold Mb in positional alignment of the mold Mb and the substrate S, similarly to the first example.

In this manner, in the imprinting device 1 according to the second example, using the pattern positional error information on the mold M (pattern manufacturing error information) which has not been used in the first example, the control unit CTL can calculate the inter-individual difference between the molds M, similarly to the first example.

Hereinabove, according to the imprinting device 1 of the second example, using the pattern positional error information for each individual mold M, the inter-individual mold difference can be corrected without using the imprinting processing or an external superposition measurement instrument to adjust an alignment offset for each individual mold M.

### Example related to article manufacturing method

For example, a method for manufacturing an article according to the present example is suitable for manufacturing microdevices such as semiconductor devices, articles such as elements having a fine structure, and the like. The method for manufacturing an article according to the present example includes forming a pattern on a composition coating a substrate using the foregoing imprinting device 1 (performing processing on a substrate), and working the substrate in which the pattern is formed in the process. Moreover, the manufacturing method includes other known processes (oxidation, film formation, vapor deposition, doping, flattening, etching, composition peeling, dicing, bonding, packaging, and the like). The method for manufacturing an article according to the present example is advantageous in at least one of performance, quality, productivity, and production cost of an article, compared to the methods in the related art. In the method for manufacturing an article according to the present example, before the imprinting processing performed by the imprinting device 1 starts, eliminating of eliminating residues of the mold (mold, original plate) is performed using the foregoing elimination device. That is, when the imprinting processing is performed, a mold from which residues have already been eliminated and in which a liquid repellent layer is formed on a mesa side wall portion of the mold is used.

The pattern of a cured product molded using the imprinting device 1 is used permanently in at least a part of various articles or temporarily during manufacturing of various articles. Examples of the articles include electric circuit elements, optical elements, MEMS, recording elements, sensors, or molds. Examples of the electric circuit elements include volatile or non-volatile semiconductor memories such as DRAM, SRAM, flash memories, or MRAM, and semiconductor elements such as LSI, CCD, image sensors, or FPGA. Examples of the molds include molds for substrate processing, such as imprinting.

The pattern of the cured product may be used as it stands as at least a part of constituent members of the foregoing article or may be used temporarily as a composition mask. After etching, ion implantation, or the like is performed during working of a substrate, the composition mask is eliminated.

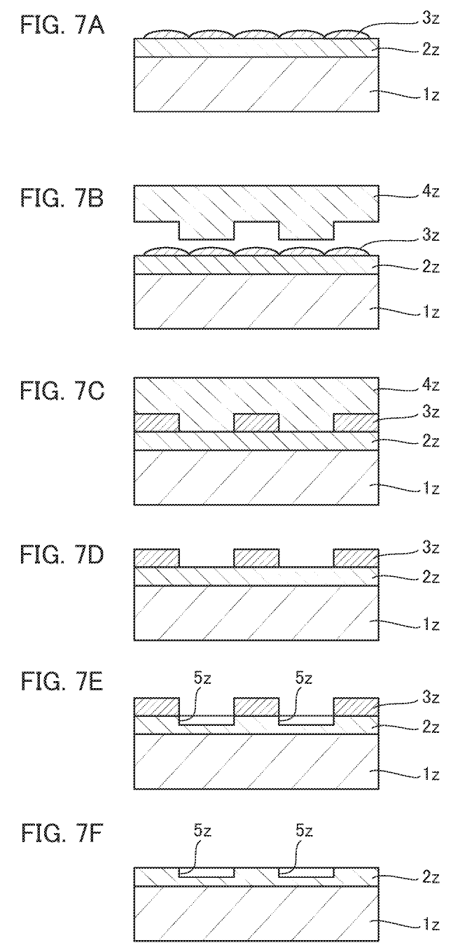

Next, a specific method for manufacturing an article will be described with reference to FIGS. 7A to 7F. As shown in FIG. 7A, a substrate 1z such as a silicon substrate having a workpiece 2z such as an insulator formed on its surface is prepared. Subsequently, a composition 3z is applied to the surface of the workpiece 2z by an inkjet method or the like. Here, a situation in which the composition 3z in a state of a plurality of droplets is applied to the substrate 1z from above is shown.

As shown in FIG. 7B, a mold 4z is set such that a side on which its uneven pattern is formed faces the composition 3z on the substrate 1z. As shown in FIG. 7C, the substrate 1z to which the composition 3z has been applied is brought into contact with the mold 4z, and a pressure is applied thereto (contacting). The composition 3z fills a gap between the mold 4z and the workpiece 2z. In this state, if irradiation is performed with light as curing energy through the mold 4z, the composition 3z is cured (curing). At this time, in the present example, the composition can be irradiated with light at an amount of irradiation corresponding to an optimal degree of photopolymerization on the basis of spectral sensitivity characteristics acquired inside the device.

As shown in FIG. 7D, after the composition 3z is cured, if the mold 4z and the substrate 1z are separated, the pattern of the cured product of the composition 3z is formed on the substrate 1z (pattern forming, molding). The pattern of this cured product has a shape in which a recessed portion of the mold 4z corresponds to a projection portion of the cured product and a projection portion of the mold 4z corresponds to a recessed portion of the cured product, that is, the uneven pattern of the mold 4z is transferred to the composition 3z.

As shown in FIG. 7E, if etching is performed using the pattern of the cured product as an etching-resistant mask, parts on the surface of the workpiece 2z where the cured product is not present or thinly remains are eliminated and become grooves 5z. As shown in FIG. 7F, if the pattern of the cured product is eliminated, an article in which the grooves 5z is formed on the surface of the workpiece 2z can be obtained. Here, the pattern of the cured product has been eliminated. However, without being eliminated even after working, for example, it may be utilized as an interlayer insulation film included in a semiconductor element or the like, namely, an article constituent member. The mold 4z has been described with an example using a mold for transferring a circuit pattern provided with an uneven pattern, but it may be a plane template having a plane portion with no uneven pattern.

Hereinabove, embodiments of the present disclosure have been described, but the present disclosure is not limited to these embodiments, and various modifications and changes can be made within a range of the gist thereof. In addition, the embodiments described above may be performed in combination.

In addition, a computer program for realizing the functions of each of the examples described above to perform a part or all of the control according to each of the embodiments described above may be supplied to the imprinting device 1 and the like via a network or various storage media. Further, a computer (or a CPU, an MPU, or the like) in the device may read and execute the program. In this case, the program and the storage medium storing the program constitute the present disclosure.

According to the present disclosure, a time required to adjust an alignment offset for each individual mold during positional alignment can be shortened.

### Other Embodiments

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

Embodiment(s) of the present invention can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

The application claims the benefit of Japanese Patent Application No. 2024-174268, filed October 3, 2024, which is hereby incorporated by reference herein in its entirety.

WHAT IS CLAIMED IS:

1. An imprinting device comprising:
a measurement unit configured to detect marks provided on a mold and a substrate;
a substrate stage configured to move in a state of holding the substrate; and
a control unit configured to control the measurement unit and the substrate stage,
wherein the mold has a first mark group and a second mark group used for positional alignment with the substrate,
the measurement unit acquires information on a relative positional relationship between the first mark group and the second mark group for each individual mold, and
the control unit controls the substrate stage to positionally align the mold and the substrate on the basis of the information on the relative positional relationship between the first mark group and the second mark group on a first mold, which is a mold different from the mold, and the mold, and information on a superposition error between the first mark group and the second mark group on the first mold and the marks on the substrate.

2. The imprinting device according to claim 1,
wherein the measurement unit acquires information on the relative positional relationship between the first mark group and the second mark group using a measurement substrate which is a substrate used only for measurement, and
when the information on the relative positional relationship is acquired, the information is acquired in a state where the mold and the measurement substrate are non-contact.

3. The imprinting device according to claim 2,
wherein the substrate and the measurement substrate have the same constitution.

4. The imprinting device according to claim 1 further comprising:
a plurality of measurement units configured to detect a plurality of marks provided on the mold and the substrate,
wherein when the plurality of marks are detected, some of the plurality of measurement units detect a mark at the same position in all measurements, and the rest detect a mark at a different position every time measurement is performed.

5. The imprinting device according to claim 1,
wherein the control unit acquires an amount of shift, which is an influence of vibration, on the basis of detection results with respect to a plurality of marks acquired at the same timing and subtracts the acquired amount of shift from the detection results.

6. The imprinting device according to claim 5,
wherein the control unit acquires an amount of positional deviation between the mold and the substrate for all marks in a pattern formation region on the substrate by integrating all the detection results from which the amount of shift has been subtracted.

7. The imprinting device according to claim 1,
wherein the control unit sets an amount of change from the first mold as a correction value in the positional alignment for each mold on the basis of the information on the relative positional relationship between the first mark group and the second mark group on the mold and the first mold.

8. The imprinting device according to claim 7,
wherein the correction value includes a magnification, a translation, a rotation, and an orthogonal component.

9. The imprinting device according to claim 1,
wherein the control unit calculates an inter-individual difference between molds using pattern manufacturing error information on the mold.

10. The imprinting device according to claim 9,
wherein the control unit acquires an amount of positional deviation of the first mark group from the pattern manufacturing error information by interpolation and extrapolation.

11. The imprinting device according to claim 1,
wherein the control unit acquires an inter-individual difference between the first mold and at least one second mold different from the first mold as a correction value at the time of the positional alignment of the mold and the substrate.

12. The imprinting device according to claim 1,
wherein the first mold is a reference mold used for calculating a difference for each individual mold.

13. The imprinting device according to claim 1 further comprising:
a mold holding unit configured to movably hold the mold,
wherein the control unit controls at least one of the substrate stage and the mold holding unit to positionally align the mold and the substrate.

14. The imprinting device according to claim 1,
wherein the mold has a pattern portion in which a predetermined pattern is formed, and
the first mark group and the second mark group are provided within a region of the pattern portion.

15. An imprinting method comprising:
detecting marks provided on a mold and a substrate having a first mark group and a second mark group; and
positionally aligning the mold and the substrate by controlling a substrate stage moving in a state of holding the substrate,
wherein in the detecting, a relative positional relationship between the first mark group and the second mark group used for positional alignment of the mold and the substrate is acquired for each individual mold, and
in the positionally aligning, the mold and the substrate are positionally aligned on the basis of information on the relative positional relationship between the first mark group and the second mark group, which has been acquired in advance, on a first mold, which is a mold different from the mold, and information on a superposition error obtained by measuring a pattern formed using the first mold.

16. A method for manufacturing an article comprising:
forming a pattern on the substrate using the imprinting device according to claim 1;
working the substrate having the pattern formed in the forming; and
manufacturing an article from the substrate worked in the working.
